(19) United States
(12) Patent Application Publication
(10) Pub. No.: US 2024/0304655 A1
(43) Pub. Date: Sep. 12, 2024

(54) BONDING TEMPERATURE MEASUREMENT DEVICE OF DISPLAY PANEL

(71) Applicant: Samsung Display Co., Ltd., Yongin-si (KR)

(72) Inventor: Jong Hyup KIM, Yongin-si (KR)

(21) Appl. No.: 18/505,034

(22) Filed: Nov. 8, 2023

(30) Foreign Application Priority Data
Mar. 8, 2023 (KR) 10-2023-0030274

(51) Int. Cl. H01L 27/15; H01L 21/66; H01L 33/36

(52) U.S. Cl. CPC H01L 27/156; H01L 22/12; H01L 33/36

(57) ABSTRACT

The present disclosure provides a display panel and a display panel bonding temperature measurement device. The display panel includes: a substrate having a display area and a non-display area; a pixel electrode in the display area; a first light emitting element bonded to the pixel electrode; a first dummy electrode in the non-display area and adjacent to the pixel electrode; a second light emitting element bonded to the first dummy electrode; and a second dummy electrode connected to the first dummy electrode and in the non-display area.

### CROSS-REFERENCE TO RELATED APPLICATION

This application claims priority to and the benefit of Korean Patent Application No. 10-2023-0030274, filed on Mar. 8, 2023, in the Korean Intellectual Property Office, the entire contents of which are incorporated herein by reference.

### BACKGROUND

### 1. Field

Aspects of embodiments of the present disclosure relate to a display panel and a display panel bonding temperature measurement device.

### 2. Description of the Related Art

As the information society develops, the demand for display devices for displaying images has increased and diversified. The display devices may be flat panel display devices, such as liquid crystal displays (LCDs), field emission displays (FEDs), or light emitting diode (LED) displays.

Light emitting diode display devices may be implemented as organic light emitting diode display devices including organic light emitting diode elements as light emitting elements, inorganic light emitting diode display devices including inorganic semiconductor elements as light emitting elements, and micro light emitting diode display devices including micro light emitting diode elements as light emitting elements.

### SUMMARY

Light emitting elements and the like may be bonded to a substrate by heat, such as by laser bonding. Laser bonding is performed by irradiating a laser beam to semiconductor elements while the light emitting elements are pressed on the substrate by a pressurizing member.

According to an embodiment, a display panel includes: a substrate having a display area and a non-display area; a pixel electrode in the display area; a first light emitting element bonded to the pixel electrode; a first dummy electrode in the non-display area and adjacent to the pixel electrode; a second light emitting element bonded to the first dummy electrode; and a second dummy electrode connected to the first dummy electrode and in the non-display area.

The display panel may further include a dummy connection electrode connecting the first dummy electrode and the second dummy electrode to each other.

The first dummy electrode and the second dummy electrode may be copper.

The first dummy electrode and the second dummy electrode may be on at least one of upper, lower, left, and right sides of the display area.

The first dummy electrode may have the same area as the pixel electrode adjacent to the first dummy electrode, and the second dummy electrode may have a greater area than the first dummy electrode.

The first dummy electrode may include a first sub-dummy electrode and a second sub-dummy electrode, and the first sub-dummy electrode and the second sub-dummy electrode may be connected to each other.

According to another embodiment, a display panel bonding temperature measurement device includes: a laser pressurizing head module for pressurizing light emitting elements respectively on a pixel electrode and a first dummy electrode of a substrate and for irradiating a laser beam to bond the light emitting elements to the pixel electrode and the first dummy electrode; and a temperature measuring member for measuring a temperature on a second dummy electrode of the substrate. The substrate has a display area and a non-display area, the first dummy electrode is in the non-display area, and the second dummy electrode is connected to the first dummy electrode.

The first dummy electrode and the second dummy electrode are copper.

The temperature measuring member may include: a temperature sensor on the second dummy electrode; a control unit for receiving a potential difference generated from the temperature sensor and processing a signal; and a temperature display unit connected to the control unit and configured to display a temperature state measured by the temperature sensor.

The temperature sensor may be a thermocouple.

The laser pressurizing head module may include: a pressurizing member including a first light transmitting member and a second light transmitting member and has a sealed space between the first light transmitting member and the second light transmitting member; a gas supply unit for supplying a gas to the sealed space to generate a pressurizing force; and a laser generator on the pressurizing member and for irradiating the laser beam in a downward direction.

The first light transmitting member may be formed of a rigid material, the second light transmitting member may be formed of an elastic material, and the first light transmitting member and the second light transmitting member may overlap a bonding area in a thickness direction.

The first light transmitting member and the second light transmitting member may overlap the second dummy electrode in the thickness direction.

The laser generator may be configured to provide area heating with respect to a bonding area.

The laser generator may be configured to radiate the laser beam to a bonding area while the second light transmitting member pressurizes the light emitting elements.

The laser pressurizing head module may include: a pressurizing member including a first light transmitting member formed of a rigid material; and a laser generator on the pressurizing member and for irradiating the laser beam in a downward direction.

The laser pressurizing head module may further include a sub-pressurizing member for pressurizing the second dummy electrode.

According to another embodiment, a display panel bonding temperature measurement device includes: a heating pressurizing head module for pressurizing light emitting elements respectively on a pixel electrode and a first dummy electrode of a substrate and for providing heat to bond the light emitting elements to the pixel electrode and the first dummy electrode; and a temperature measuring member for measuring a temperature on a second dummy electrode of the substrate. The substrate has a display area and a non-display area, the first dummy electrode is in the non-display area, and the second dummy electrode is connected to the first dummy electrode.

The heating pressurizing head module may include: a pressurizing member including a first light transmitting member formed of a rigid material and for pressuring a bonding area; and a sub-pressurizing member for pressurizing the second dummy electrode; and a laser generator on the pressurizing member and for irradiating a laser beam in a downward direction.

The temperature measuring member may include: a temperature sensor on the second dummy electrode; a control unit for receiving a potential difference generated by the temperature sensor and for processing a signal; and a temperature display unit connected to the control unit and configured to display a temperature state measured by the temperature sensor. The temperature sensor may be a thermocouple.

Accordingly, heat may be generated by, for example, the laser, which may deteriorate the light emitting elements. Accordingly, a temperature change of the substrate due to the heat can occur.

Further, it is difficult to directly measure a temperature of the substrate in a bonding area at the time of performing the bonding.

Embodiment of the present disclosure provide a display panel and a display panel bonding temperature measurement device that can accurately measure a temperature of a substrate in a bonding area without directly measuring the temperature of the substrate in the bonding area at the time of bonding.

According to embodiments, a temperature of a substrate at the time of bonding between the substrate and light emitting elements by heat may be accurately measured.

However, aspects and features the present disclosure are not limited to those mentioned above, and various other aspects and features are included in the present disclosure.

### BRIEF DESCRIPTION OF THE DRAWINGS

The above and other aspects and features of the present disclosure will become more apparent by describing, in detail, embodiments thereof with reference to the attached drawings, in which:

FIG. 1 is a layout diagram of a display device according to an embodiment;

FIG. 2 is a schematic view of a pixel shown in FIG. 1;

FIG. 3 is a schematic view of the pixel shown in FIG. 1 according to another embodiment;

FIG. 4 is a cross-sectional view taken along the line A-A′ of FIG. 2;

FIG. 5 is a schematic view of a pixel electrode, a light emitting element, a common electrode, and a third planarization layer according to an embodiment;

FIG. 6 is a layout diagram of a first dummy electrode and a second dummy electrode according to an embodiment;

FIG. 7 is a layout diagram of a display device according to another embodiment;

FIG. 8 is a layout diagram of a first dummy electrode and a second dummy electrode according to another embodiment;

FIGS. 9 and 10 are layout diagrams of a display device according to other embodiments;

FIG. 11 is a schematic diagram of a display panel bonding temperature measurement device according to an embodiment;

FIG. 12 is an enlarged view of a temperature sensor and a dummy pattern shown in FIG. 11;

FIG. 13 is a plan view of a bonding area of a display panel;

FIG. 14 is an exploded perspective view of a laser pressurizing member according to an embodiment;

FIG. 15 is a side view of the laser pressurizing member shown in FIG. 14 according to an embodiment;

FIG. 16 is a cross-sectional view of a laser pressurizing member according to an embodiment;

FIG. 17 is a cross-sectional view illustrating gas filling into a sealed space of a laser pressurizing member according to another embodiment;

FIG. 18 is a cross-sectional view illustrating gas exhausted from the laser pressurizing member according to another embodiment;

FIG. 19 is a schematic diagram of a display panel bonding temperature measurement device according to another embodiment; and

FIG. 20 is a schematic diagram illustrating a display panel bonding temperature measurement device according to still another embodiment.

### DETAILED DESCRIPTION

The embodiments will now be described more fully hereinafter with reference to the accompanying drawings. These embodiments may, however, be provided in different forms and should not be construed as limiting. Some of the parts of embodiments described herein that are not associated with the present disclosure may not be shown or described to more clearly describe aspects and features of the present disclosure.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. For example, the expression “at least one of a, b, or c” indicates only a, only b, only c, both a and b, both a and c, both b and c, all of a, b, and c, or variations thereof. As used herein, the terms “use,” “using,” and “used” may be considered synonymous with the terms “utilize,” “utilizing,” and “utilized,” respectively.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The terms “about” or “approximately” as used herein is inclusive of the stated value and means within an acceptable range of deviation for the particular value as determined by one of ordinary skill in the art, considering the measurement in question and the error associated with measurement of the particular quantity (e.g., the limitations of the measurement system). For example, “about” may mean within one or more standard deviations, or within ±30%, 20%, 10%, 5% of the stated value.

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

Hereinafter, embodiments of the present disclosure will be described, in detail, with reference to the accompanying drawings.

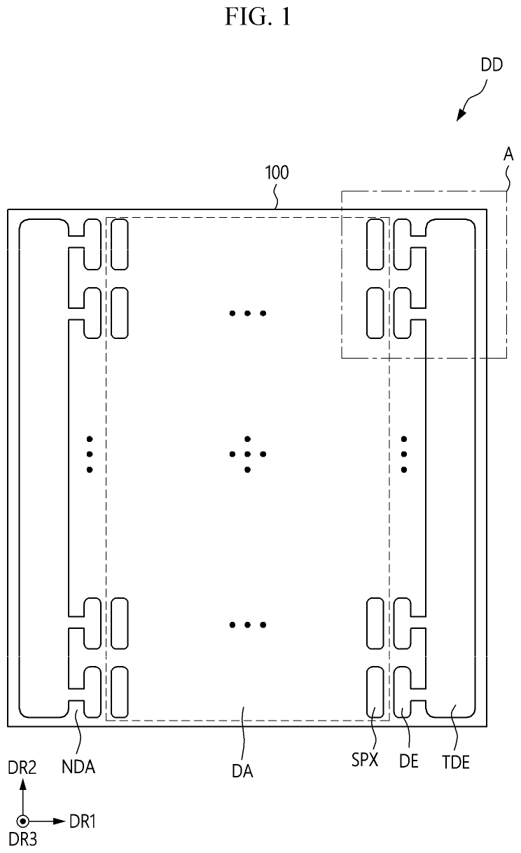

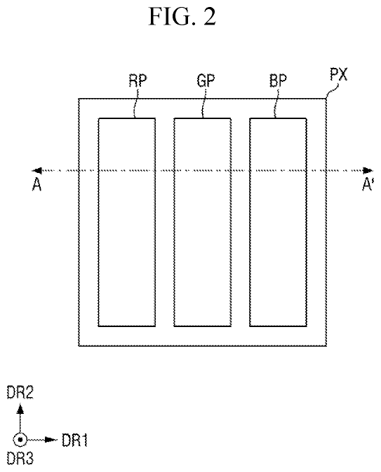

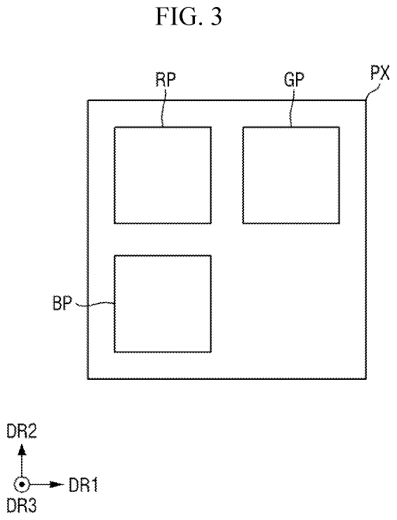

FIG. 1 is a layout diagram (also referred to as a schematic diagram) of a display device according to an embodiment. FIG. 2 is a schematic view of a pixel show in FIG. 1. FIG. 3 is a schematic view the pixel shown in FIG. 1 according to another embodiment.

Referring to FIGS. 1 to 3, a display device DD is a device that is configured to display a moving image and/or a still image and may be used as a display screen of various products, such as televisions, laptop computers, monitors, billboards, and Internet of Things (IOT) devices, as well as portable electronic devices, such as mobile phones, smartphones, tablet personal computers (PCs), smart watches, watch phones, mobile communication terminals, electronic notebooks, electronic books, portable multimedia players (PMPs), navigation devices, and ultra mobile PCs (UMPCs).

A display panel 100 may be formed in a rectangular shape, in a plan view, having long sides in a first direction DR1 and short sides in a second direction DR2 crossing the first direction DR1. A corner at where the long side in the first direction DR1 and the short side in the second direction DR2 meet may be rounded with a curvature (e.g., a predetermined curvature) or may be right-angled. The shape of the display panel 100 in a plan view is not limited to the rectangular shape and may be other polygonal shapes, a circular shape, or an elliptical shape. The display panel 100 may be flat but is not limited thereto. For example, the display panel 100 may have curved surface parts (or areas) at left and right ends thereof and may have a constant curvature or a variable curvature. In addition, the display panel 100 may be flexibly formed to be curved, bent, folded, or rolled.

The display panel 100 may further include pixels, scan lines extending in the first direction DR1, and data lines extending in the second direction DR2 to display an image. The pixels PX may be arranged in a matrix form in the first direction DR1 and the second direction DR2.

The display panel 100 may have a display area DA for displaying an image and a non-display area NDA, which is a peripheral area of the display area DA. The display area DA may occupy most of the display panel 100. The display area DA may be disposed at the center of the display panel 100.

The non-display area NDA may be disposed to neighbor to the display area DA. The non-display area NDA may be an area outside the display area DA. The non-display area NDA may be disposed to surround (e.g., to extend around a periphery of or to surround in a plan view) the display area DA. The non-display area NDA may be an edge area (or a peripheral area) of the display panel 100.

The display area DA may include a plurality of pixels for displaying an image. The pixels are provided on the display area DA of the display panel 100. Each pixel is a minimum (or smallest) unit for displaying an image, and the plurality of pixels may be provided. The pixels may emit white light and/or color light. The pixel may emit any one of red, green, and blue colors but is not limited thereto and may emit a different color, such as cyan, magenta, or yellow.

The non-display area NDA may include first dummy electrodes DE and second dummy electrodes TDE.

The second dummy electrode TDE may be connected to a plurality of first dummy electrodes DE. The second dummy electrodes TDE may be disposed on both sides (e.g., left and right sides) of the display panel 100 but are not limited thereto.

Each of the pixels may include a plurality of sub-pixels SPX as illustrated in FIGS. 2 and 3. FIGS. 2 and 3 illustrate embodiments in which each of the pixels PX includes three sub-pixels SPX, that is, a first sub-pixel RP, a second sub-pixel GP, and a third sub-pixel BP, but the present disclosure is not limited thereto.

Each of the first sub-pixel RP, the second sub-pixel GP, and the third sub-pixel BP may be connected to any one of the data lines and at least one of the scan lines.

Each of the first sub-pixel RP, the second sub-pixel GP, and the third sub-pixel BP may have a rectangular shape, a square shape, or a rhombic shape in a plan view. For example, each of the first sub-pixel RP, the second sub-pixel GP, and the third sub-pixel BP may have a rectangular shape, in a plan view, having short sides in the first direction DR1 and long sides in the second direction DR2, as illustrated in FIG. 2. In another embodiment, each of the first sub-pixel RP, the second sub-pixel GP, and the third sub-pixel BP may have a square or rhombic shape, in a plan view, including sides having the same length in the first direction DR1 and the second direction DR2, as illustrated in FIG. 3.

As illustrated in FIG. 2, the first sub-pixel RP, the second sub-pixel GP, and the third sub-pixel BP may be arranged in the first direction DR1. In another embodiment, any one of the second sub-pixel GP and the third sub-pixel BP and the first sub-pixel RP may be arranged in the first direction DR1, and the other of the second sub-pixel GP and the third sub-pixel BP and the first sub-pixel RP may be arranged in the second direction DR2. For example, as illustrated in FIG. 3, the first sub-pixel RP and the second sub-pixel GP are arranged in the first direction DR1, and the first sub-pixel RP and the third sub-pixel BP are arranged in the second direction DR2.

In another embodiment, any one of the first sub-pixel RP and the third sub-pixel BP and the second sub-pixel GP may be arranged in the first direction DR1, and the other of the first sub-pixel RP and the third sub-pixel BP and the second sub-pixel GP may be arranged in the second direction DR2. In another embodiment, any one of the first sub-pixel RP and the second sub-pixel GP and the third sub-pixel BP may be arranged in the first direction DR1, and the other of the first sub-pixel RP and the second sub-pixel GP and the third sub-pixel BP may be arranged in the second direction DR2.

The first sub-pixel RP may include a first light emitting element for emitting first light, the second sub-pixel GP may include a second light emitting element for emitting second light, and the third sub-pixel BP may include a third light emitting element for emitting third light. In one embodiment, the first light may be light in a red wavelength band, the second light may be light in a green wavelength band, and the third light may be light in a blue wavelength band. The red wavelength band may be a wavelength band having a range of approximately 600 nm to approximately 750 nm, the green wavelength band may be a wavelength band having a range of approximately 480 nm to approximately 560 nm, and the blue wavelength band may be a wavelength band having a range of approximately 370 nm to approximately 460 nm, but the present disclosure is not limited thereto.

Each of the first sub-pixel RP, the second sub-pixel GP, and the third sub-pixel BP may include an inorganic light emitting element including an inorganic semiconductor as a light emitting element emitting light. For example, the inorganic light emitting element may be a flip chip-type micro light emitting diode (LED), but the present disclosure is not limited thereto.

As illustrated in FIGS. 2 and 3, an area of the first sub-pixel RP, an area of the second sub-pixel GP, and an area of the third sub-pixel BP may be substantially the same as each other, but the present disclosure is not limited thereto. At least one of an area of the first sub-pixel RP, an area of the second sub-pixel GP, and an area of the third sub-pixel BP may be different from another of the area of the first sub-pixel RP, the area of the second sub-pixel GP, and the area of the third sub-pixel BP. In another embodiment, any two of an area of the first sub-pixel RP, an area of the second sub-pixel GP, and an area of the third sub-pixel BP may be the same as each other, and the other of the area of the first sub-pixel RP, the area of the second sub-pixel GP, and the area of the third sub-pixel BP may be different from the two of the area of the first sub-pixel RP, the area of the second sub-pixel GP, and the area of the third sub-pixel BP. In another embodiment, an area of the first sub-pixel RP, an area of the second sub-pixel GP, and an area of the third sub-pixel BP may be different from each other.

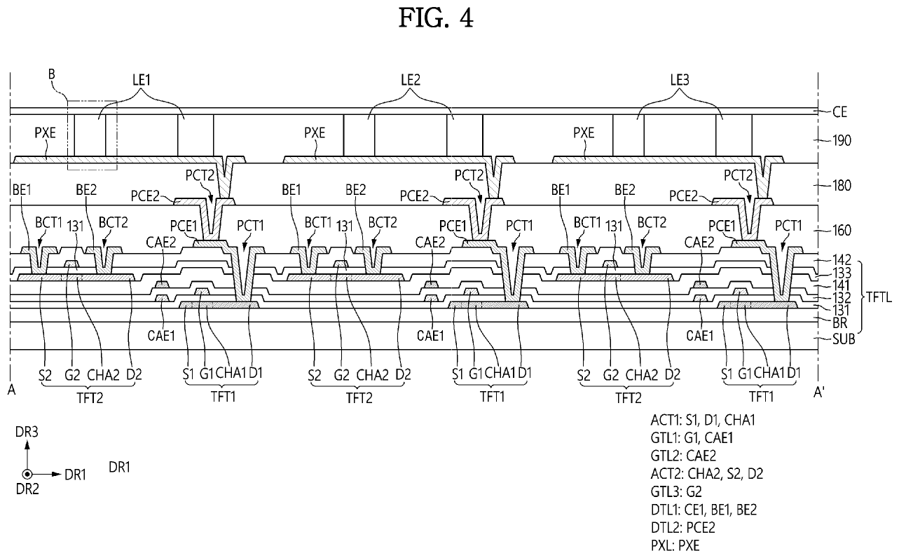

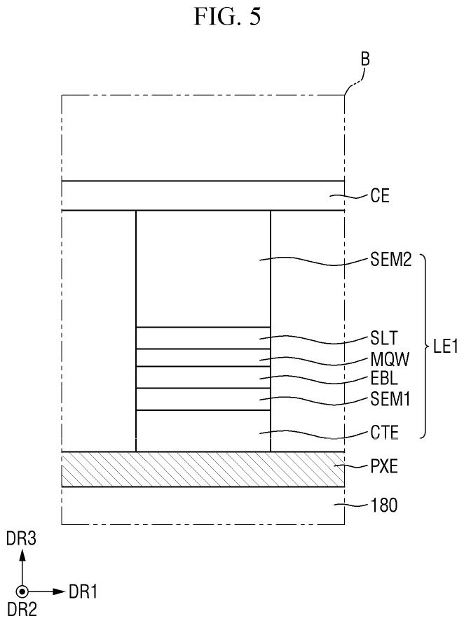

FIG. 4 is a cross-sectional view of a display panel taken along the line A-A′ of FIG. 2. FIG. 5 is a schematic view of a pixel electrode, a light emitting element, a common electrode, and a third planarization layer according to an embodiment. FIG. 5 is an enlarged cross-sectional view of the area B in FIG. 4.

Referring to FIGS. 4 and 5, a barrier layer BR may be disposed on a substrate SUB. The substrate SUB may be made of an insulating material, such as a polymer resin. For example, the substrate SUB may be made of polyimide. The substrate SUB may be a flexible substrate that may be bent, folded, and rolled.

The barrier layer BR is a film for protecting transistors of a thin film transistor layer TFTL from moisture permeating through the substrate SUB, which may be vulnerable to moisture permeation. The barrier layer BR may include a plurality of inorganic films that are alternately stacked. For example, the barrier layer BR may be formed as multiple films in which one or more inorganic films of a silicon nitride layer, a silicon oxynitride layer, a silicon oxide layer, a titanium oxide layer, and an aluminum oxide layer are alternately stacked.

Each of first thin film transistors TFT1 may include a first active layer ACT1 and a first gate electrode G1.

The first active layers ACT1 of the first thin film transistors TFT1 may be disposed on the barrier layer BR. The first active layer ACT1 of the first thin film transistor TFT1 may include polycrystalline silicon, single crystal silicon, low-temperature polycrystalline silicon, or amorphous silicon.

The first active layer ACT1 may include a first channel region CHA1, a first source region S1, and a first drain region D1. The first channel region CHA1 may be a region overlapping the first gate electrode G1 in a third direction DR3, which is a thickness direction of the substrate SUB. The first source region S1 may be disposed on one side of the first channel region CHA1, and the first drain region D1 may be disposed on another side (e.g., an opposite side) of the first channel region CHA1. The first source region S1 and the first drain region D1 may be regions that do not overlap (e.g., are offset from) the first gate electrode G1 in the third direction DR3. The first source region S1 and the first drain region D1 may be regions having conductivity by doping a silicon semiconductor or an oxide semiconductor with ions.

A first gate insulating layer 131 may be disposed on the first active layer ACT1 of the first thin film transistor TFT1. The first gate insulating layer 131 may be formed as an inorganic layer, such as a silicon nitride layer, a silicon oxynitride layer, a silicon oxide layer, a titanium oxide layer, or an aluminum oxide layer.

A first gate metal layer GTL1 may be disposed on the first gate insulating layer 131. The first gate metal layer GTL1 may include the first gate electrode G1 of the first thin film transistor TFT1 and a first capacitor electrode CAE1. The first gate electrode G1 may overlap the first channel region CHA1 in the third direction DR3. FIG. 4 illustrates an embodiment in which the first gate electrode G1 and the first capacitor electrode CAE1 are disposed to be spaced apart from each other, but the first gate electrode G1 and the first capacitor electrode CAE1 may be connected to each other. The first gate metal layer GTL1 may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof.

A second gate insulating layer 132 may be disposed on the first gate electrode G1 of the first thin film transistor TFT1 and the first capacitor electrode CAE1. The second gate insulating layer 132 may be formed as an inorganic layer, such as a silicon nitride layer, a silicon oxynitride layer, a silicon oxide layer, a titanium oxide layer, or an aluminum oxide layer.

A second gate metal layer GTL2 may be disposed on the second gate insulating layer 132. The second gate metal layer GTL2 may include a second capacitor electrode CAE2. The second capacitor electrode CAE2 may overlap the first capacitor electrode CAE1 in the third direction DR3. Because the second gate insulating layer 132 has a dielectric constant (e.g., a predetermined or known dielectric constant), a capacitor may be formed by the first capacitor electrode CAE1, the second capacitor electrode CAE2, and the second gate insulating layer 132 disposed between the first capacitor electrode CAE1 and the second capacitor electrode CAE2. The second gate metal layer GTL2 may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof.

A first interlayer insulating layer 141 may be disposed on the second capacitor electrode CAE2. The first interlayer insulating layer 141 may be formed as an inorganic layer, such as a silicon nitride layer, a silicon oxynitride layer, a silicon oxide layer, a titanium oxide layer, or an aluminum oxide layer.

Second thin film transistors TFT2 may be disposed on the first interlayer insulating layer 141. Each of the second thin film transistors TFT2 may include a second active layer ACT2 and a second gate electrode G2.

The second active layers ACT2 of the second thin film transistors TFT2 may be disposed on the first interlayer insulating layer 141. The second active layer ACT2 may include an oxide semiconductor. For example, the second active layer ACT2 may include IGZO (indium (In), gallium (Ga), zinc (Zn), and oxygen (O)), IGZTO (indium (In), gallium (Ga), zinc (Zn), tin (Sn), and oxygen (O)), or IGTO (indium (In), gallium (Ga), tin (Sn) and oxygen (O)).

The second active layer ACT2 may include a second channel region CHA2, a second source region S2, and a second drain region D2. The second channel region CHA2 may be a region overlapping the second gate electrode G2 in the third direction DR3. The second source region S2 may be disposed on one side of the second channel region CHA2, and the second drain region D2 may be disposed on the other side of the second channel region CHA2. The second source region S2 and the second drain region D2 may be regions that do not overlap the second gate electrode G2 in the third direction DR3. The second source region S2 and the second drain region D2 may be regions having conductivity by doping an oxide semiconductor with ions.

A third gate insulating layer 133 may be disposed on the second active layer ACT2 of the second thin film transistor TFT2. The third gate insulating layer 133 may be formed as an inorganic layer, such as a silicon nitride layer, a silicon oxynitride layer, a silicon oxide layer, a titanium oxide layer, or an aluminum oxide layer.

A third gate metal layer GTL3 may be disposed on the third gate insulating layer 133. The third gate metal layer GTL3 may include the second gate electrode G2 of the second thin film transistor TFT2. The second gate electrode G2 may overlap the second active layer ACT2 in the third direction DR3. The third gate metal layer GTL3 may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof.

A second interlayer insulating layer 142 may be disposed on the second gate electrode G2 of the second thin film transistor TFT2. The second interlayer insulating layer 142 may be formed as an inorganic layer, such as a silicon nitride layer, a silicon oxynitride layer, a silicon oxide layer, a titanium oxide layer, or an aluminum oxide layer.

A first data metal layer DTL1 may be disposed on the second interlayer insulating layer 142. The first data metal layer DTL1 may include a first pixel connection electrode PCE1, a first connection electrode BE1, and a second connection electrode BE2. The first pixel connection electrode PCE1 may be connected to the first drain region D1 of the first active layer ACT1 through a first pixel connection hole (e.g., a first pixel connection opening) PCT1 penetrating through the first gate insulating layer 131, the second gate insulating layer 132, the first interlayer insulating layer 141, the third gate insulating layer 133, and the second interlayer insulating layer 142. The first connection electrode BE1 may be connected to the second source region S2 of the second active layer ACT2 through a first connection contact hole (e.g., a first connection contact opening) BCT1 penetrating through the second interlayer insulating layer 142. The second connection electrode BE2 may be connected to the second drain region D2 of the second active layer ACT2 through a second connection contact hole (e.g., a second connection contact opening) BCT2 penetrating through the second interlayer insulating layer 142. The first data metal layer DTL1 may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof. For example, the first data metal layer DTL1 may include a first layer made of titanium (Ti), a second layer made of aluminum (Al), and a third layer made of titanium (Ti).

A first organic layer 160 for planarizing a step due to the first thin film transistor TFT1 and the second thin film transistor TFT2 may be disposed on the first pixel connection electrode PCE1, the first connection electrode BE1, and the second connection electrode BE2. The first organic layer 160 may be formed as an organic layer made of an acrylic resin, an epoxy resin, a phenolic resin, a polyamide resin, a polyimide resin, or the like.

A second data metal layer DTL2 may be disposed on the first organic layer 160. The second data metal layer DTL2 may include a second pixel connection electrode PCE2. The second pixel connection electrode PCE2 may be connected to the first pixel connection electrode CE1 through a second pixel connection hole (e.g., a second pixel connection opening) PCT2 penetrating through the first organic layer 160. The second data metal layer DTL2 may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof. For example, the second data metal layer DTL2 may include a first layer made of titanium (Ti), a second layer made of aluminum (Al), and a third layer made of titanium (Ti).

A second organic layer 180 may be disposed on the second pixel connection electrode PCE2. The second organic layer 180 may be formed as an organic layer made of an acrylic resin, an epoxy resin, a phenolic resin, a polyamide resin, a polyimide resin, or the like.

A light emitting element layer EML may be disposed on the second organic layer 180. The light emitting element layer EML may include pixel electrodes PXE, light emitting elements LE1, LE2, and LE3, a common electrode CE, and a planarization layer 190.

A pixel electrode layer PXL may be disposed on the second organic layer 180. The pixel electrode layer PXL may include the pixel electrodes PXE. Each of the pixel electrodes PXE may be connected to the second pixel connection electrode PCE2 through a third pixel connection hole (e.g., a third pixel connection opening) CT3 penetrating through the second organic layer 180. Thus, each of the pixel electrodes PXE may be connected to a first electrode S1 or a second electrode D1 of the thin film transistor TFT through the first pixel connection electrode PCE1 and the second pixel connection electrode PCE2. Therefore, a pixel voltage or an anode voltage controlled by (e.g., output by) the thin film transistor TFT may be applied to the pixel electrode PXE.

The pixel electrode layer PXL may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof. Because the pixel electrodes PXE are bonded to first light emitting elements LE1, second light emitting elements LE2, or third light emitting elements LE3, lower sheet resistances of the pixel electrodes PXE may reduce contact resistance between the pixel electrodes PXE and the first light emitting elements LE1, the second light emitting elements LE2, or the third light emitting elements LE3. For example, the pixel electrode layer PXL may be made of copper (Cu), which has low sheet resistance.

Each of the first light emitting element LE1, the second light emitting element LE2, and the third light emitting element LE3 may be disposed on the pixel electrode PXE. In the illustrated embodiment, each of the first light emitting element LE1, the second light emitting element LE2, and the third light emitting element LE3 is a vertical micro LED extending in the third direction DR3.

Each of the first light emitting element LE1, the second light emitting element LE2, and the third light emitting element LE3 may be formed of an inorganic material, such as GaN. Each of the first light emitting element LE1, the second light emitting element LE2, and the third light emitting element LE3 may have a length in a range of several to several hundreds of micrometers in each of the first direction DR1, the second direction DR2, and the third direction DR3. For example, each of the first light emitting element LE1, the second light emitting element LE2, and the third light emitting element LE3 may have a length in a range of approximately 100 μm or less in each of the first direction DR1, the second direction DR2, and the third direction DR3.

Each of the first light emitting element LE1, the second light emitting element LE2, and the third light emitting element LE3 may be grown and formed on a semiconductor substrate, such as a silicon wafer. Each of the first light emitting element LE1, the second light emitting element LE2, and the third light emitting element LE3 may be directly transferred from the silicon wafer onto the pixel electrode PXE of the substrate SUB.

Each of the first light emitting element LE1, the second light emitting element LE2, and the third light emitting element LE3 may include a contact electrode CTE, a first semiconductor layer SEM1, an electron blocking layer EBL, an active layer MQW, a superlattice layer SLT, and a second semiconductor layer SEM2.

The contact electrode CTE may be disposed on the pixel electrode PXE. The contact electrode CTE and the pixel electrode PXE may be bonded to each other through a soldering process. For example, the contact electrode CTE may include at least one of gold (Au), copper (Cu), aluminum (Al), and tin (Sn). A solder used in the soldering process may have a relatively low melting point and a high capacity. For example, the solder may be an alloy of tin, lead, silver, copper, and the like.

The first semiconductor layer SEM1 may be disposed on the contact electrode CTE. The first semiconductor layer SEM1 may be made of GaN doped with a first conductivity-type dopant, such as Mg, Zn, Ca, Se, or Ba.

The electron blocking layer EBL may be disposed on the first semiconductor layer SEM1. The electron blocking layer EBL may be a layer for suppressing or preventing too many electrons from flowing to the active layer MQW. For example, the electron blocking layer EBL may be made of p-AlGaN doped with p-type Mg. In some embodiments, the electron blocking layer EBL may be omitted.

The active layer MQW may be disposed on the electron blocking layer EBL. The active layer MQW may emit light by a combination of electron-hole pairs according to electrical signals applied through the first semiconductor layer SEM1 and the second semiconductor layer SEM2.

The active layer MQW may include a material having a single or multiple quantum well structure. When the active layer MQW includes the material having the multiple quantum well structure, the active layer MQW may have a structure in which a plurality of well layers and barrier layers are alternately stacked. In such an embodiment, the well layer may be made of InGaN, and the barrier layer may be made of GaN or AlGaN, but the present disclosure is not limited thereto. In another embodiment, the active layer MQW may have a structure in which semiconductor materials having large band gap energy and semiconductor materials having small band gap energy are alternately stacked and may include other Group III to Group V semiconductor materials depending on a wavelength band of light to be emitted.

When the active layer MQW includes InGaN, a color of the light emitted by the active layer MQW may be varied depending on a content of indium (In). For example, as the content of indium (In) increases, a wavelength band of the light emitted by the active layer may move toward a red wavelength band, and as the content of indium (In) decreases, a wavelength band of the light emitted by the active layer may move toward a blue wavelength band. Therefore, a content of indium (In) in the active layer MQW of the first light emitting element LE1 for emitting the first light, which is the light of the red wavelength band, may be higher than a content of indium (In) in the active layer MQW of the second light emitting element LE2, and a content of indium (In) in the active layer MQW of the second light emitting element LE2 may be higher than a content of indium (In) in the active layer MQW of the third light emitting element LE3. For example, the content of indium (In) in the active layer MQW of the first light emitting element LE1 may be in a range of approximately 30 wt % to approximately 40 wt %, the content of indium (In) in the active layer MQW of the second light emitting element LE2 may be in a range of approximately 20 wt % to approximately 30 wt %, and content of indium (In) in the active layer MQW of the third light emitting element LE3 may be in a range of approximately 10 wt % to approximately 20 wt %. In such an embodiment, the active layer MQW of the first light emitting element LE1 may emit the first light, the active layer MQW of the second light emitting element LE2 may emit the second light, and the active layer MQW of the third light emitting element LE3 may emit the third light.

The superlattice layer SLT may be disposed on the active layer MQW. The superlattice layer SLT may be a layer for alleviating stress between the second semiconductor layer SEM2 and the active layer MQW. For example, the superlattice layer SLT may be made of InGaN or GaN. In some embodiments, the superlattice layer SLT may be omitted.

The second semiconductor layer SEM2 may be disposed on the superlattice layer SLT. The second semiconductor layer SEM2 may be doped with a second conductivity-type dopant, such as Si, Ge, or Sn. For example, the second semiconductor layer SEM2 may be made of n-GaN doped with n-type Si.

The planarization layer 190 may be disposed on side surfaces of each of the first light emitting elements LE1, the second light emitting elements LE2, and the third light emitting elements LE3. The planarization layer 190 may be a layer for planarizing a step due to the first light emitting elements LE1, the second light emitting elements LE2, and the third light emitting elements LE3. Upper surfaces of the first light emitting elements LE1, upper surfaces of the second light emitting elements LE2, upper surfaces of the third light emitting elements LE3, and an upper surface of the planarization layer 190 may be flatly connected to each other (e.g., may have a planar upper surface). The planarization layer 190 may be formed as an organic layer made of an acrylic resin, an epoxy resin, a phenolic resin, a polyamide resin, a polyimide resin, or the like.

The common electrode CE may be disposed on the upper surfaces of the first light emitting elements LE1, the upper surfaces of the second light emitting elements LE2, the upper surfaces of the third light emitting elements LE3, and the upper surface of the planarization layer 190. The common electrode CE may be a common layer formed in common in the first sub-pixel SPX1, the second sub-pixel SPX2, and the third sub-pixel SPX3. The common electrode CE may be made of transparent conductive oxide (TCO), such as indium tin oxide (ITO) or indium zinc oxide (IZO) capable of transmitting light therethrough.

As illustrated in FIGS. 4 and 5, because the pixel electrodes PXE bonded to the first light emitting elements LE1, the second light emitting elements LE2, or the third light emitting elements LE3, when the pixel electrodes PXE are made of copper (Cu) having the low sheet resistance, contact resistance between the pixel electrodes PXE and the first light emitting elements LE1, the second light emitting elements LE2, or the third light emitting elements LE3 may be reduced.

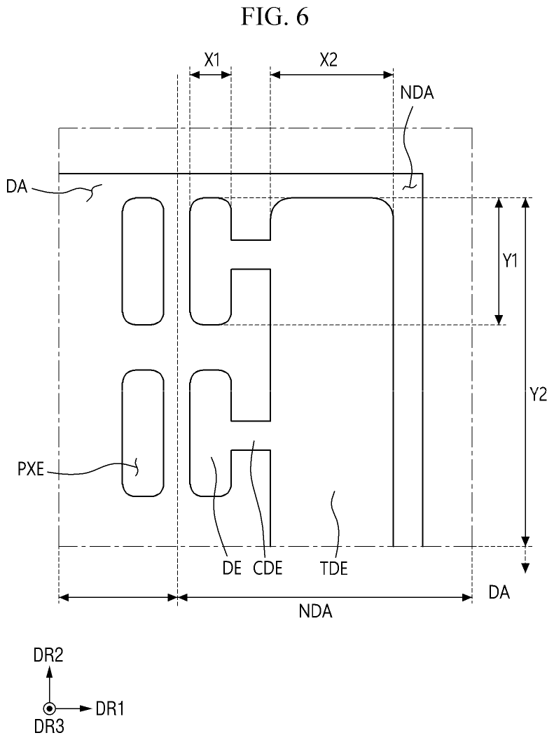

FIG. 6 is a schematic view a first dummy electrode and a second dummy electrode according to an embodiment. FIG. 6 is an enlarged cross-sectional view of the area A in FIG. 1.

The first dummy electrode DE is disposed to neighbor to a pixel electrode PXE of a sub-pixel.

The first dummy electrode DE may be disposed between the neighboring pixel electrode PXE and the second dummy electrode TDE. An area of the first dummy electrode DE may be substantially the same as an area of the pixel electrode PXE, but the present disclosure is not limited thereto. The first dummy electrode DE may have the same shape as the pixel electrode PXE but is not limited thereto. The first dummy electrode DE may be formed of the same material as the pixel electrode PXE. Accordingly, the first dummy electrode DE may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof.

The second dummy electrode TDE may be connected to the first dummy electrode DE through a dummy connection electrode CDE. The first dummy electrode DE, the dummy connection electrode CDE, and the dummy electrode TDE may be formed of the same material. Accordingly, the dummy connection electrode CDE and the dummy electrode TDE may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof.

A length Y2 of the second dummy electrode TDE in the second direction DR2 may be greater than a length (e.g., a width) X2 of the second dummy electrode TDE in the first direction DR1.

The length X2 of the second dummy electrode TDE in the first direction DR1 may be greater than a length (e.g., a width) X1 of the first dummy electrode DE1 in the first direction DR1, and the length Y2 of the second dummy electrode TDE in the second direction DR2 may be greater than the length (e.g., the width) X2 of the second dummy electrode TDE in the first direction DR1. The second dummy electrode TDE may be in contact with a temperature measurement sensor in a temperature measurement process, to be described later.

The dummy connection electrode CDE may be disposed between the first dummy electrode DE and the second dummy electrode TDE, and an area of the dummy connection electrode CDE may be smaller than that of the first dummy electrode DE.

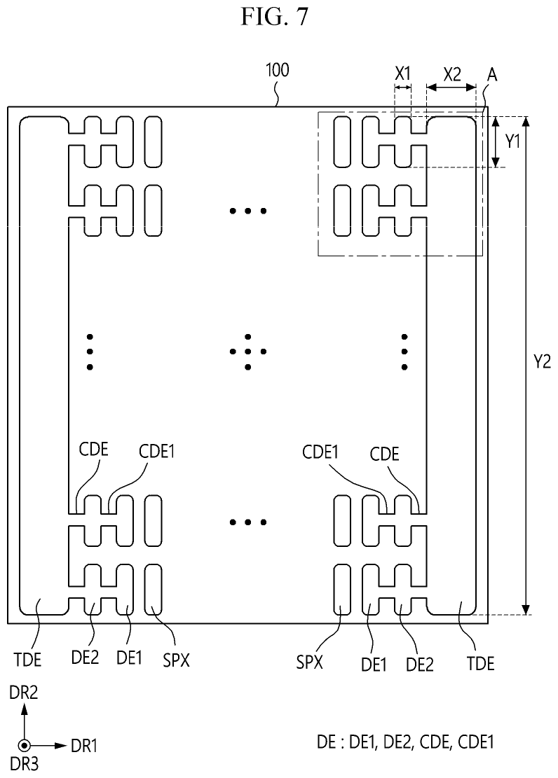

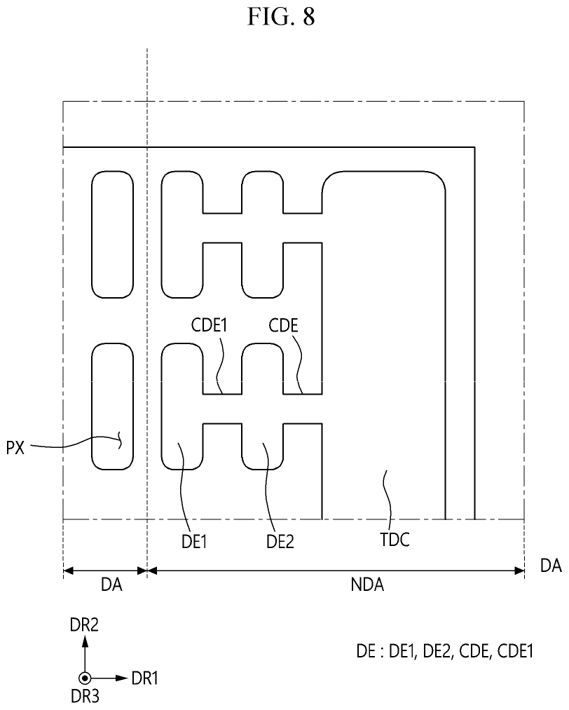

FIG. 7 is a layout diagram schematically illustrating a display device according to another embodiment, and FIG. 8 is a schematic view of a first dummy electrode and a second dummy electrode according to another embodiment. FIG. 8 is an enlarged cross-sectional view of the area A in FIG. 7.

Referring to FIGS. 7 and 8, the display panel 100 may have a display area DA for displaying an image and a non-display area NDA, which is a peripheral area of the display area DA. The non-display area NDA may include first dummy electrodes DE, second dummy electrodes TDE, and dummy connection electrodes CDE.

The first dummy electrode DE may include a plurality of sub-dummy electrodes DE1 and DE2. As an example, as illustrated in FIG. 7, the first dummy electrode DE may include a first sub-dummy electrode DE1 and a second sub-dummy electrode DE2.

The first sub-dummy electrode DE1 and the second sub-dummy electrode DE2 are connected to each other by a sub-dummy connection electrode CDE1.

Each of the first sub-dummy electrode DE1 and the second sub-dummy electrode DE2 may have the same shape as the pixel electrode PXE but is not limited thereto. The first sub-dummy electrode DE1 and the second sub-dummy electrode DE2 may be formed of the same material as the pixel electrode PXE. Accordingly, the first sub-dummy electrode DE1 and the second sub-dummy electrode DE2 may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof.

The second dummy electrode TDE may be connected to the first dummy electrode DE through the dummy connection electrode CDE. The first dummy electrode DE, the dummy connection electrode CDE, and the dummy electrode TDE may be formed of the same material. Accordingly, the dummy connection electrode CDE and the dummy electrode TDE may be formed as a single layer or multiple layers made of any one of molybdenum (Mo), aluminum (Al), chromium (Cr), gold (Au), titanium (Ti), nickel (Ni), neodymium (Nd), and copper (Cu), or alloys thereof.

A length Y2 of the second dummy electrode TDE in the second direction DR2 may be greater than a length (e.g., a width) X2 of the second dummy electrode TDE in the first direction DR1.

The display panel 100 may include a plurality of pixels for displaying an image. The pixels have already been described in detail with reference to FIGS. 1 to 4 and will not be described again.

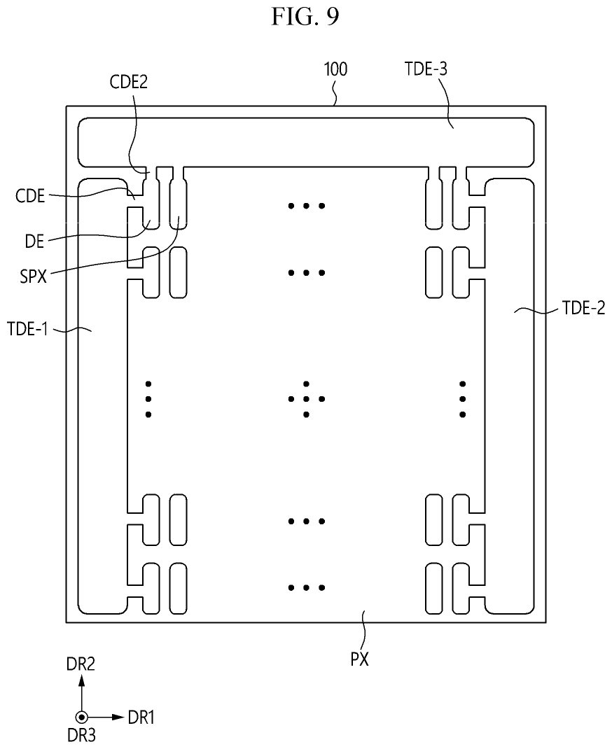

FIG. 9 is a layout diagram schematically illustrating a display device according to another embodiment.

The embodiment illustrated in FIG. 9 differs from the embodiment illustrated in FIGS. 1 to 6 in that first dummy electrodes and second dummy electrodes are disposed on three side surfaces of the display panel 100. Hereinafter, content different from that described above will be primarily described, and a description of the same or substantially the same configuration(s) described above with reference to FIGS. 1 to 6 will be omitted.

The display panel 100 has a display area DA and a non-display area NDA.

Sub-pixel electrodes SPX are disposed in the display area DA, and first dummy electrodes DE and second dummy electrodes TDE1, TDE2, and TDE3 are disposed in the non-display area NDA.

The first dummy electrodes DE and the second dummy electrodes TDE1, TDE2, and TDE3 may be disposed on the left and right sides and the upper side of the display panel 100 but are not limited thereto. The first dummy electrodes DE and the second dummy electrode TDE1, TDE2, and TDE3 may be disposed on three or more of the upper, lower, left, and right sides of the display panel 100.

When the first dummy electrodes DE and the second dummy electrodes TDE1, TDE2, and TDE3 are disposed on three or more of the upper, lower, left, and right sides of the display panel 100 as described above, the first dummy electrodes DE disposed at the corner of the display panel 100 may be connected to two second dummy electrodes neighboring thereto.

By disposing the second dummy electrodes DE on several places of the display panel 100, temperatures of different points may be measured by a temperature measuring member, to be described later, such that accuracy of temperature measurement may be improved.

FIG. 10 is a layout diagram schematically illustrating a display device according to another embodiment.

The embodiment illustrated in FIG. 10 is different from the embodiment illustrated in FIGS. 1 to 6 in that first dummy electrodes and a second dummy electrode are disposed on one (e.g., are disposed only on one) side surface of the display panel. Hereinafter, content(s) different from that described above will be primarily described, and a description of the same or substantially the same configuration(s) described above with reference to FIGS. 1 to 6 will be omitted.

The display panel 100 has a display area DA and a non-display area NDA.

Sub-pixel electrodes SPX are disposed in the display area DA, and first dummy electrodes DE and a second dummy electrode TDE are disposed in the non-display area NDA.

The first dummy electrode DE and the second dummy electrode TDE may be disposed on any one of the upper, lower, left, and right sides of the display panel 100.

As can be seen with reference to FIGS. 1, 9, and 10, the first dummy electrodes DE and the second dummy electrodes TDE may be disposed on one or more of the upper, lower, left, and right sides of the non-display area NDA of the display panel 100.

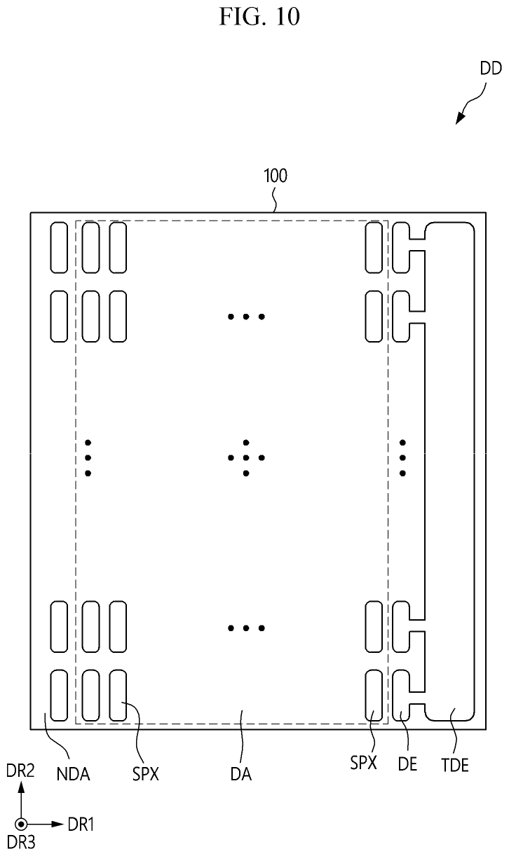

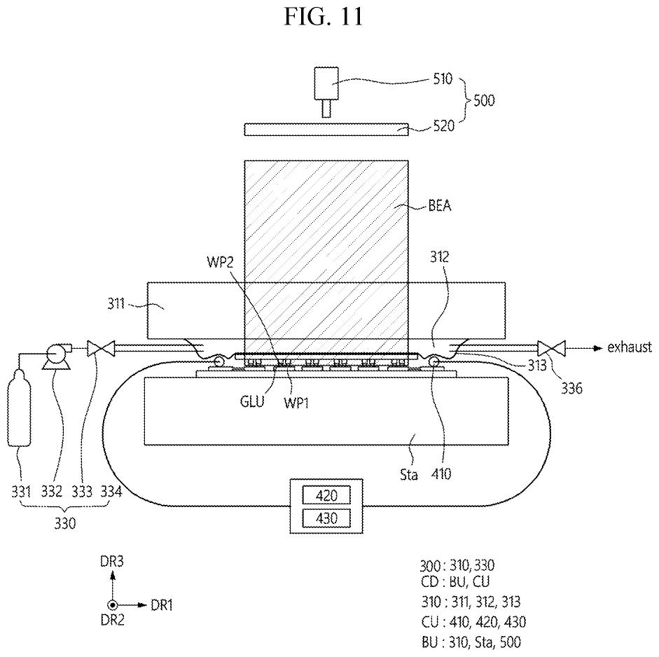

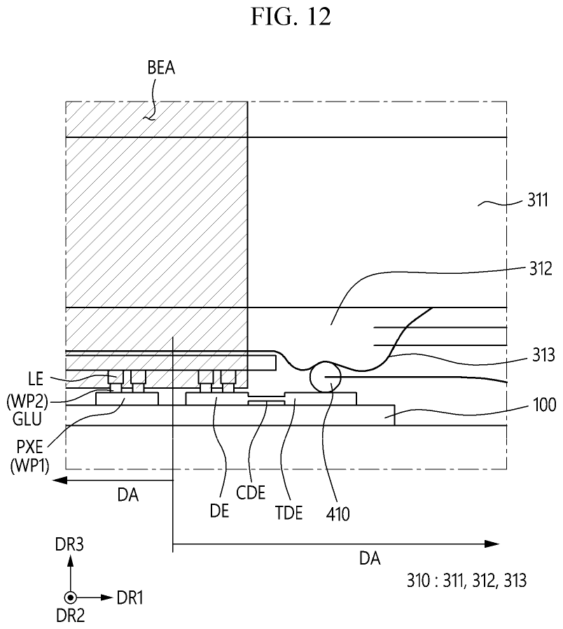

FIG. 11 is a schematic diagram of a display panel bonding temperature measurement device according to an embodiment, and FIG. 12 is an enlarged view of a temperature sensor and a dummy pattern shown in FIG. 11. In addition, FIG. 13 is a plan view of a bonding area on a display panel.

Referring to FIGS. 11 and 12, a display panel bonding temperature measurement device CD may include a laser bonding member BU and a temperature measuring member CU.

The laser bonding member BD may bond two or more bonding objects WP1 and WP2 to each other by using a laser beam. The bonding objects WP1 and WP2 may be bonded and electrically connected to each other. The bonding objects WP1 and WP2 may be substrates, films, display panels, touch panels, printed circuit boards, flexible circuit boards, or semiconductor devices, such as light emitting elements. As an example, according to an embodiment, first bonding objects WP1 may be substrates and second bonding objects WP2 may be light emitting elements, but the present disclosure is not limited thereto.

The laser bonding member BU may include a laser pressurizing head module 300, a support member Sta, and a laser generator 500.

The laser generator 500 may include a laser light source 510 and an optical system 520.

The laser light source 510 is a device configured to generate a laser light by energy supplied from the outside, and may be, for example, a solid laser, such as a YAG laser, a ruby laser, a glass laser, a YVO₄ laser, a LD laser, or a fiber laser, a liquid laser, such as a dye laser, a gas laser, such as a CO₂ laser, an excimer laser (e.g., a ArF laser, a KrF laser, a XeCl laser, a XeF laser, etc.), an Ar laser, or a He—Ne laser, a semiconductor laser, or a free electron laser.

The optical system 520 may receive the laser light in the form of a beam from the laser light source 510 and may perform optical dispersion to enable area heating with respect to an area (e.g., a predetermined area).

The laser light emitted from the optical system 520 may be irradiated to the bonding objects WP1 and WP2 and may heat areas (e.g., predetermined areas) of the bonding objects WP1 and WP2. The laser light emitted from the optical system 520 may have a wavelength range of about 250 nm to about 5μ. However, the present disclosure is not limited thereto.

In some embodiments, an output and the like of the laser light source 510 may be adjusted in consideration of a melting point of an adhesive member GLU disposed between the bonding objects WP1 and WP2. The adhesive member GLU may be a non-conductive film (NCF), an anisotropic conductive film (ACF), an instant adhesive, an ultrasonic curable adhesive, a non-conductive paste (NCF), and the like but is not particularly limited.

The laser light may allow the bonding objects WP1 and WP2 to be bonded to each other by heating the adhesive member GLU.

The support member Sta has an upper surface parallel to a plane defined by the first direction DR1 and the second direction DR2, which are perpendicular to each other, and the bonding objects WP1 and WP2 are seated on the upper surface of the support member Sta.

The support member Sta and the laser generator 500 may be disposed on a straight line in the third direction DR3 to overlap each other on the plane. For example, a laser beam generated from the laser generator 500 is irradiated in a direction toward the support member Sta.

The laser generator 500 is separately formed independently from the laser pressurizing head module 300 and, thus, may move to a plurality of irradiation positions on the bonding objects WP1 and WP2 in a state in which the bonding objects WP1 and WP2 are pressed by the laser pressurizing head module 300. Reduction of tact time at one irradiation position and a speed increase of a bonding work for all of the plurality of irradiation positions may be realized.

The laser pressurizing head module 300 may include a pressurizing member 310 and a gas supply unit 330.

The pressurizing member 310 may include a first light transmitting member 311 and a second light transmitting member 313 and may include a sealed space 312 between the first light transmitting member 311 and the second light transmitting member 313. The first light transmitting member 311 and the second light transmitting member 313 may be disposed on a straight line to overlap each other on a plane.

Each of the first light transmitting member 311 and the second light transmitting member 313 may be formed in a rectangular shape, in a plan view, having long sides in the first direction DR1 and short sides in the second direction DR2 crossing the first direction DR1. A corner at where the long side in the first direction DR1 and the short side in the second direction DR2 meet may be right-angled. The shape of each of the first light transmitting member 311 and the second light transmitting member 313 in a plan view is not limited to the rectangular shape and may be other polygonal shapes, a circular shape, or an elliptical shape.

The first light transmitting member 311 may be formed of a rigid light transmitting material to pass the laser light emitted from the laser generator 500 therethrough. Here, the light transmitting material may be defined as a material capable of passing 80% or more of light energy of the laser light emitted from the laser generator 500 therethrough. For example, the first light transmitting member 311 may be made of a material capable of exhibiting a light transmittance of about 80% or more with respect to light of a wavelength range of about 250 nm to about 5 μm but is not limited thereto.

In addition, the first light transmitting member 311 may be made of any material capable of withstanding a pressure inside the sealed space 312, for example, a pressure in a range of about 0.1 MPa to about 5 MPa based on a gauge pressure. The first light transmitting member 311 may be made of a material, such as tempered glass, quartz, acryl, metal oxide, or a metalloid oxide, such as silicon oxide or aluminum oxide. However, the present disclosure is not limited thereto.

The second light transmitting member 313 may be formed of a light transmitting material having elasticity to pass the laser light emitted from the laser generator 500 therethrough. For example, the second light transmitting member 313 may be formed as a silicon multilayer, a silicon-polyethylene terephthalate (PET) stacked layer, or the like. However, the present disclosure is not limited thereto.

Because the second light transmitting member 313 is formed of the light transmitting material having the elasticity, a phenomenon in which the second light transmitting member 313 is not in contact with the bonding objects when it pressurizes the bonding objects may be reduced or minimized.

The second light transmitting member 313 expands in a downward direction, that is, in the direction toward the support member Sta, by the pressure inside the sealed space 312 to generate a pressurizing force in the downward direction.

The gas supply unit 330 may generate a pressurizing force by supplying a gas to the sealed space 312 between the first light transmitting member 311 and the second light transmitting member 313.

The gas supply unit 330 may supply gases that are inert or have extremely low chemical reactivity, such as nitrogen (N₂), helium (He), neon (Ne), argon (Ar), carbon dioxide (CO₂), or mixtures thereof to the sealed space 312. Hereinafter, the gases that are inert or have the extremely low chemical reactivity as described above are collectively referred to as neutral gases.

The gas supply unit 330 may include a reservoir 331 for storing the gas, a gas pump 332 for pressurizing and supplying the gas, a gas valve 333 for adjusting a flow of the gas, and a gas supply conduit 334 providing a path through which the gas is supplied into the sealed space 312. In addition, the gas supply unit 330 may further include a gas exhaust conduit 335 and an exhaust valve 336 for exhausting the gas that has generated the pressurizing force in the sealed space 312.

The gas pump 332 may be configured to supply the gas into the sealed space 312 at a pressure higher than a pressure outside the sealed space 312 (e.g., at a positive pressure). The gas pump 332 may be configured to supply the gas to the sealed space 312 until the pressure inside the sealed space 312 reaches between about 0.1 MPa to about 5 MPa based on the gauge pressure, but is not limited thereto.

The gas valve 333 may be closed so that the supply of the gas is stopped and the pressure inside the sealed space 312 is maintained when the pressure inside the sealed space 312 is sufficiently high. The gas valve 333 may be, for example, a ball valve, a globe valve, a gate valve, a control valve, or the like but is not particularly limited.

The laser light may allow the second bonding objects WP2 to be bonded to the first bonding objects WP1 by heating the bonding objects WP1 and WP2, which will be described later in more detail.

After the processing of the bonding objects WP1 and WP2 is completed, the pressure inside the sealed space 312 may be lowered. To this end, the gas exhaust conduit 335 and the exhaust valve 336 may be provided. The exhaust valve 336 may be in a closed state while the pressure inside the sealed space 312 rises and while the rising (or positive) pressure is maintained.

After the processing of the bonding objects WP1 and WP2 is completed, the exhaust valve 336 is opened so that the glass in the sealed space 312 may be exhausted to the outside of the sealed space 312 through the gas exhaust conduit 335. The exhaust valve 336 may be, for example, a ball valve, a globe valve, a gate valve, a control valve, or the like but it is not particularly limited.

For convenience of explanation, a direction in which the laser beam is irradiated is defined as a downward direction, and a direction opposite to the downward direction is defined as an upward direction, and a direction opposite to the downward direction and the downward direction are parallel to the third direction DR3 defined as a direction orthogonal to each of the first direction DR1 and the second direction DR2. The third direction DR3 may be a reference direction for distinguishin front and rear surfaces of components, to be described later, from each other. However, the upward direction or the downward direction is a relative concept and may be converted into other directions.

The temperature measuring member CU is a member (e.g., a component) for sensing and displayihng a temperature and may include a temperature sensor 410, a control unit 420, and a temperature display unit 430.

The temperature sensor 410 may be a thermocouple. The thermocouple is a sensor manufactured by bonding two differnet metals to each other and measures a temperature by measuring a potential difference (e.g., a voltage) generated accordig to a change in temperature. The thermocouple measures a temperature by using the principle of a thermoelectric effect of two metals. The thermoelectric effect is a phenomenon in which a potential difference is generated while electrons move when heat is transferred between metals when two or more different metals are bonded to each other. The thermoelectric effect is associated with a temperature difference between the two metals, and the thermocouple measures the temperature by using the thermoelectric effect.

The thermocouple generally uses a metal, such as platinum, tungsten, lead, copper, and a copper-nickel alloy (e.g., constantan). When a temperature changes at a point where the two metals are bonded to each other, the potential difference is generated due the thermoelectric effect of the two metals. By measuring such a potential difference, the temperature change may be known.

In an embodiment, the first bonding object WP1 may be a display panel 100, and the second bonding object WP2 may be a light emitting element LE. The display panel 100 may be the display panel 100 described above with reference to FIGS. 1 to 6.

The pixel electrodes PXE and the first dummy electrodes DE on the display panel 100 are positioned withihn a bonding area BEA heated by the laser light irradiated from the laser light source 510. As illustrated in FIG. 13, the bonding area BEA may include a display area DA and a first dummy pattern are DEA.

The second dummy pattern TDE is positioned outside the bonding are BEA and, thus, is not directly heated. The second dummy pattern TDE is connected to the first dummy pattern DE positioned within the bonding area BEA by the dummy connection electrode CDE having high thermal conductivity. Accordigly, a temperature of the second dummy pattern TDE may become equal to a temperature of the first dummy pattern DE. For example, a bonding temperature of the first dummy pattern DE may be indirectly measured by measuring the temperature of the second dummy pattern TDE.

To this end, the temperature sensor 410 is positioned on the second dummy pattern TDE to sense the temperature of the second dummy patter TDE. The temperature sensor 410 is disposed between the second light transmitting member 313 and the second dummy pattern TDE. The temperature sensor 410 receives the pressurizing force in the downward direction by the second light transmitting member 313 at the time bonding is performed.

The control unit 420 receives the potential difference generated from the temperature sensor 410 as a signal and processes the signal.

The temperature display unit 430 is connected to the control unit 420 and primarily displays a temperature state measured by the temperature sensor 410. The temperature display unit 430 may display the temperature in numbers or may use a method of displaying a temperature section simply by changing a LED color.

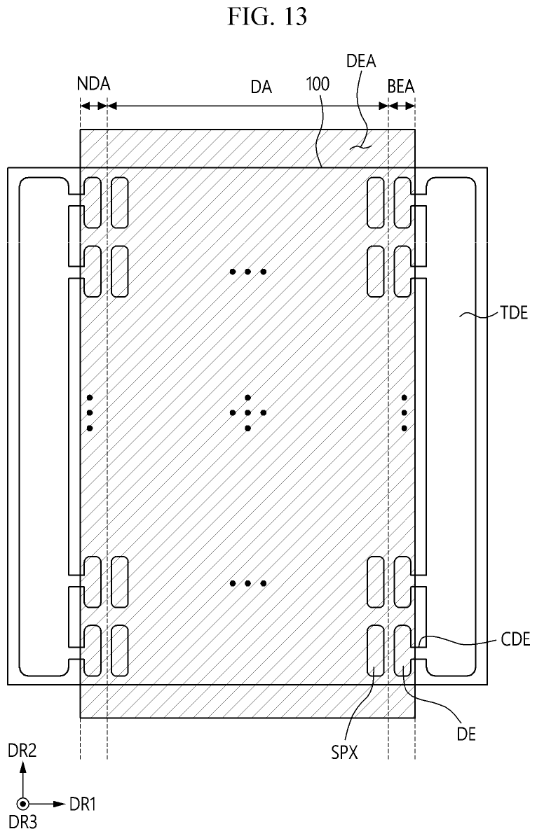

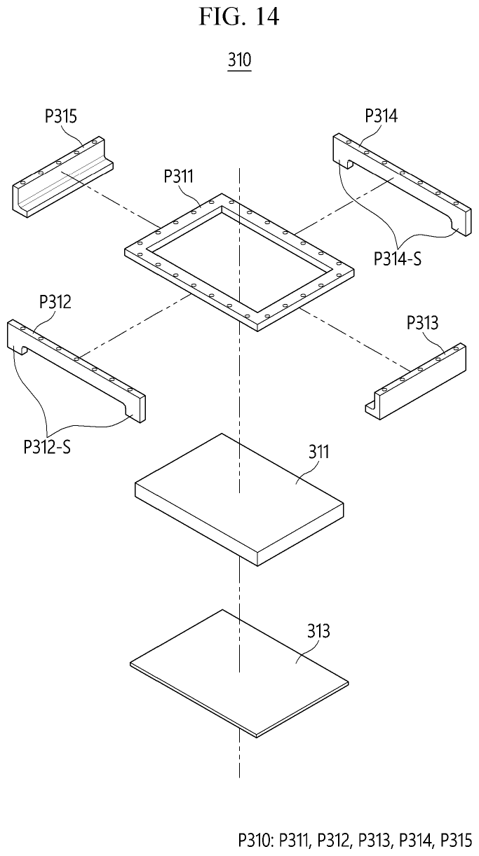

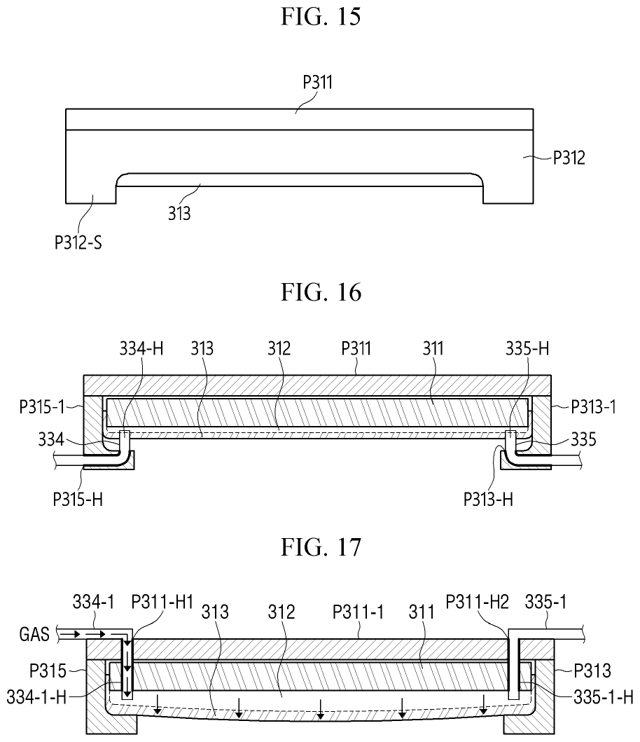

FIG. 14 is an exploded perspective view of a laser pressurizing member according to embodiments, and FIG. 15 is a side view of the laser pressurizing member shown in FIG. 14.

Referring to FIGS. 14 and 15, a laser pressurizing member may include a picture frame P310 and a first light transmitting member 311 and a second light transmitting member 313 accommodated in the picture frame P310.

The picture frame P310 may include a main frame P311 having a rectangular frame shape in a plan view and first to fourth side frames P312, P313, P314, and P315 connected to (e.g., vertically connected to) four sides of the main frame P311, respectively.

The main frame P311 has an upper surface parallel to a plane defined by the first direction DR1 and the second direction DR2, which are perpendicular to each other, and has a rear surface in a direction opposite to the upper surface in a third direction DR3.

The main frame P311 of the picture frame P310 is formed in a rectangular frame shape having an opening formed to expose one surface of the first light transmitting member 311. The laser beam irradiated from the laser generator 500 (see, e.g., FIG. 11) passes through the first light transmitting member 311 and the second light transmitting member 313 through the opening in the main frame P311.

In some embodiments, a light blocking member may be provided on the upper surface of the main frame P311 having the rectangular frame shape, but the present disclosure is not limited thereto.

The light blocking member may block transmission of light. The light blocking member may include an organic light blocking material and a liquid repellent component. Here, the liquid repellent component may be made of a fluorine-containing monomer or a fluorine-containing polymer and, specifically, may include a fluorine-containing aliphatic polycarbonate. For example, the light blocking member may be made of a black organic material including a liquid repellent component. The light blocking member may be formed through coating and exposing processes or the like of an organic light blocking material including a liquid repellent component.

Some of the first to fourth side frames P312, P313, P314, and P315, for example, the second side frame P313 and the fourth side frame P315 facing the second side frame P313 may be bent in an “L” shape. First surfaces of the frames bent in the “L” shape as described above may be perpendicular to the main frame P311 and may be in contact with side surfaces of the first light transmitting member 311, and second surfaces of the frames perpendicular to the first surfaces may be parallel to the main frame P311 and may be in contact with a rear surface of the second light transmitting member 313. The main frame P311 and the first to fourth side frames P312, P313, P314, and P315 may be screwed to each other but are not limited thereto.

Some of the first to fourth side frames P312, P313, P314, and P315, for example, the first side frame P312 and the third side frame P314 facing the first side frame P312 may include leg parts P312-S and P314-S protruding in the downward direction, respectively. The leg parts P312-S and P314-S support the picture frame P310 outside an irradiation area of the laser beam during a period in which the laser beam is irradiated. The irradiation area of the laser beam is an area at which the laser beam is incident when the laser beam is irradiated in a state in which the laser generator 500 (see, e.g., FIG. 11) or the support member Sta (see, e.g., FIG. 11) is fixed.

In another embodiment, the main frame P311 and the first to fourth side frames P312, P313, P314, and P315 may be formed integrally with each other.

The first light transmitting member 311 and the second light transmitting member 313 are disposed in an accommodation space formed by (e.g., surrounded along its periphery by) the first to fourth side frames P312, P313, P314, and P315. Accordingly, the rear surface of the main frame P311 may be in contact with an upper surface of the first light transmitting member 311, and the first to fourth side frames P312, P313, P314, and P315 may be in contact with side surfaces of the first light transmitting member 311 and the second light transmitting member 313. The main frame P311 and the first light transmitting member 311 may be disposed on a straight line to overlap each other in the thickness direction on a plane.

In the embodiment illustrated in FIGS. 13 and 14, the picture frame P310 has been described, but the present disclosure is not limited thereto. For example, the picture frame P310 may be implemented as a ‘⊏’-shaped frame capable of supporting the first light transmitting member 311 and the second light transmitting member 313.

FIG. 16 is a cross-sectional view of a laser pressurizing member according to an embodiment.

Referring to FIG. 16, to fill the gas in the sealed space 312 between the first light transmitting member 311 and the second light transmitting member 313, one end of the gas supply conduit 334 and one end of the gas exhaust conduit 335 may be provided in the sealed space 312.

The gas supply conduit 334 and the gas exhaust conduit 335 may pass through the second light transmitting member 313 and may be connected to the sealed space 312. To this end, the second light transmitting member 313 may have through holes (e.g., openings) 334-H and 335-H for connecting the gas supply conduit 334 and the gas exhaust conduit 335, respectively. The gas supply conduit 334 may be connected to the sealed space 312 through a first through hole 334-H, and the gas exhaust conduit 335 may be connected to the sealed space 312 through a second through hole 335-H.

In addition, some of the first to fourth side frames P312, P313, P314, and P315, for example, the second side frame P313-1 and the fourth side frame P315-1, may have, respectively, through holes P313-H and P315-H for connecting the gas supply conduit 334 and the gas exhaust conduit 335. The gas supply conduit 334 may be connected to the sealed space 312 through a fourth through hole P315-H, and the gas exhaust conduit 335 may be connected to the sealed space 312 through a third through hole P313-H.

Referring to FIG. 16, the gas supply conduit 334 is connected to the sealed space 312 through the fourth through hole P315-H in the fourth side frame P315-1 and the first through hole 334-H in the second light transmitting member 313. The gas is filled in the sealed space 312 through the gas supply conduit 334. In this case, the gas exhaust conduit 335 may be blocked by the exhaust valve 336 (see, e.g., FIG. 11) described above.

Referring to FIG. 16, the gas exhaust conduit 335 is connected to the sealed space 312 through the third through hole P313-H in the second side frame P313-1 and the second through hole 335-H in the second light transmitting member 313. The gas is exhausted from the sealed space 312 to the outside through the gas exhaust conduit 335. In this case, the gas supply conduit 334 may be blocked by the gas valve 333 (see, e.g., FIG. 11) described above.

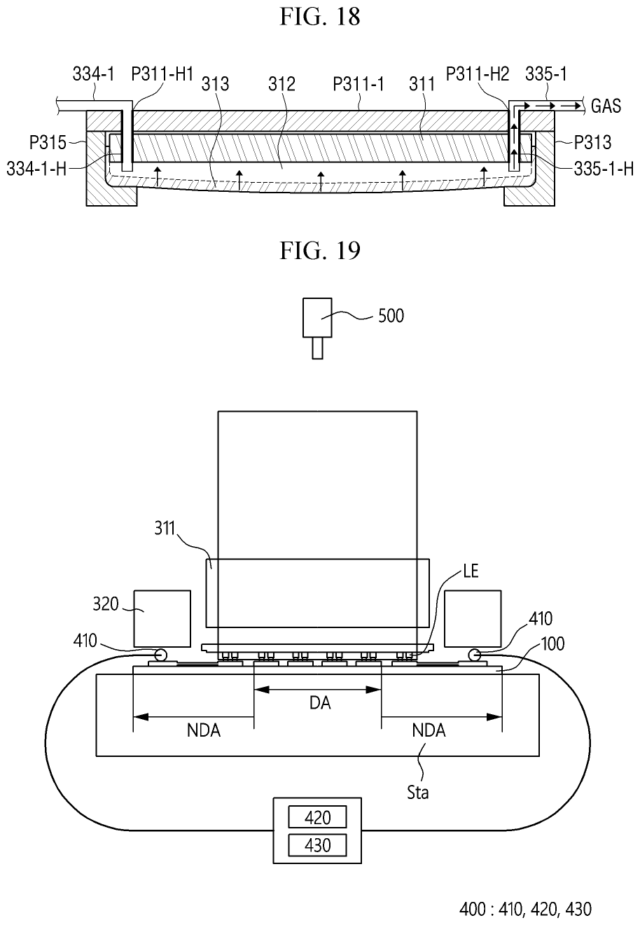

FIG. 17 is a cross-sectional view illustrating gas filling into a sealed space of a laser pressurizing member according to another embodiment, and FIG. 18 is a cross-sectional view illustrating gas exhaust from the laser pressurizing member according to embodiment shown in FIG. 17.

Referring to FIGS. 17 and 18, to fill the gas in the sealed space 312 between the first light transmitting member 311 and the second light transmitting member 313, one end of a gas supply conduit 334-1 and one end of a gas exhaust conduit 335-1 may be provided in the sealed space 312.

The gas supply conduit 334-1 and the gas exhaust conduit 335-1 may pass through the first light transmitting member 311 and may be connected to the sealed space 312. To this end, the first light transmitting member 311 may have through holes 334-1-H and 335-1-H for connecting the gas supply conduit 334-1 and the gas exhaust conduit 335-1, respectively. The gas supply conduit 334-1 may be connected to the sealed space 312 through a fifth through hole 334-1-H, and the gas exhaust conduit 335-1 may be connected to the sealed space 312 through a sixth through hole 335-1-H.

In addition, the main frame P311 may have through holes P311-H1 and P311-H2 connecting the gas supply conduit 334-1 and the gas exhaust conduit 335-1. The gas supply conduit 334-1 may be connected to the sealed space 312 through a seventh through hole 311-H1, and the gas exhaust conduit 335-1 may be connected to the sealed space 312 through an eighth through hole 311-H2.

Referring to FIG. 17, the gas supply conduit 334-1 is connected to the sealed space 312 through the seventh through hole P311-H1 in the main frame P311 and the fifth through hole 334-1-H in the first light transmitting member 311. The gas is filled in the sealed space 312 through the gas supply conduit 334-1. In this case, the gas exhaust conduit 335-1 may be blocked by an exhaust valve thereto.

Referring to FIG. 18, the gas exhaust conduit 335-1 is connected to the sealed space 312 through the eighth through hole P311-H2 in the main frame P311 and the sixth through hole 335-1-H in the first light transmitting member 311. The gas is exhausted from the sealed space 312 to the outside through the gas exhaust conduit 335-1. In this case, the gas supply conduit 334-1 may be blocked by a gas valve connected thereto.

FIG. 19 is a schematic diagram of a display panel bonding temperature measurement device according to another embodiment.

The embodiment illustrated in FIG. 19 is different from the embodiment illustrated in FIG. 11 in that the pressurizing member 310 of the laser pressurizing head module 300 includes only one light transmitting member and includes a sub-pressurizing member 320. Hereinafter, content(s) different from that described above will be primarily described, and a description of the same or substantially the same configuration(s) described above with reference to FIG. 11 will be omitted.

Referring to FIG. 19, the pressurizing member 310 may include a first light transmitting member 311.

The first light transmitting member 311 may be formed in a rectangular shape, in a plan view, having long sides in the first direction DR1 and short sides in the second direction DR2 crossing the first direction DR1. A corner at where the long side in the first direction DR1 and the short side in the second direction DR2 meet may be right-angled. The shape of the first light transmitting member 311 in a plan view is not limited to the rectangular shape and may be other polygonal shapes, a circular shape, or an elliptical shape.

The first light transmitting member 311 may be formed of a rigid light transmitting material to pass the laser light emitted from the laser generator 500 therethrough. The light transmitting material may be defined as a material capable of passing 80% or more of light energy of the laser light emitted from the laser generator 500 therethrough. For example, the first light transmitting member 311 may be made of a material capable of exhibiting a light transmittance of about 80% or more with respect to light of a wavelength range between about 250 nm to about 5 μm but is not limited thereto.

The laser pressurizing head module 300 includes the sub-pressurizing member 320. The sub-pressurizing member 320 is disposed on the second dummy pattern and pressurizes the temperature sensor 410 in the thickness direction.

When the sub-pressurizing member 320 pressurizes the bonding area in synchronization with the first light transmitting member 311, the first light transmitting member 311 may pressurize the second dummy electrode TDE, but the present disclosure is not limited thereto.

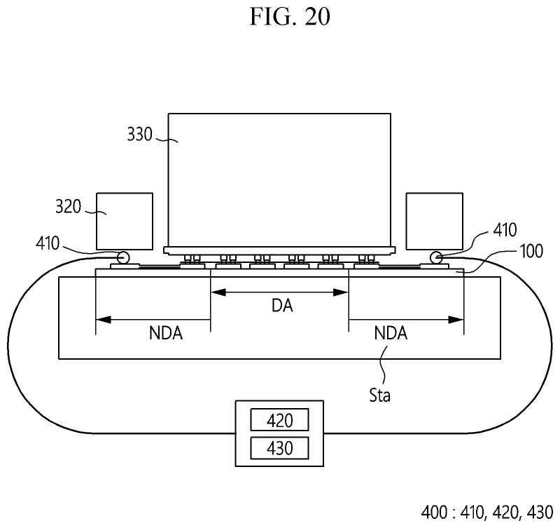

FIG. 20 is a schematic diagram of a display panel bonding temperature measurement device according to another embodiment.

The embodiment illustrated in FIG. 20 is different from the embodiment illustrated in FIG. 11 in that the laser pressurizing head module 300 uses a hot tool heating method and does not use a laser and includes a sub-pressurizing member 320. Hereinafter, content(s) different from those described above will be primarily described, and a description of the same or substantially the same configuration(s) described above with reference to FIG. 11 will be omitted.

Referring to FIG. 20, the pressurizing member 310 may be heated by the hot tool heating method and may perform pressurization in the thickness direction. The pressurizing member 310 may include a hot plate receiving electricity to emit heat. The hot plate may be formed in a rectangular shape, in a plan view, having long sides in the first direction DR1 and short sides in the second direction DR2 crossing the first direction DR1. A corner at where the long side in the first direction DR1 and the short side in the second direction DR2 meet may be right-angled. The shape of the hot plate in a plan view is not limited to the rectangular shape and may be other polygonal shapes, a circular shape, or an elliptical shape.

The laser pressurizing head module 300 includes the sub-pressurizing member 320. The sub-pressurizing member 320 is disposed on the second dummy pattern and pressurizes the temperature sensor 410 in the thickness direction.

When the sub-pressurizing member 320 pressurizes the bonding area in synchronization with the pressurizing member 310, the pressurizing member 310 may pressurize the second dummy electrode TDE, but the present disclosure is not limited thereto.

As described above, the display panel according to an embodiment includes the first dummy electrode disposed in the non-display area and the second dummy electrode disposed in the non-display area and connected to the first dummy electrode. Further, the first dummy electrode is disposed in the bonding area and transfers heat generated at the time of bonding to the second dummy electrode. Thus, the second dummy electrode maintains the same or substantially the same temperature as the first dummy electrode disposed in the bonding area even though it is not disposed in (e.g., is outside of) the bonding area. Accordingly, the temperature sensor may accurately report (or estimate) the temperature of the bonding area by measuring the temperature of the second dummy electrode.

However, aspects and features of the present disclosure are not limited to those described herein. The above and other aspects and features of the present disclosure will become more apparent to one of ordinary skill in the art to which the disclosure pertains by referencing the claims, with equivalents thereof to be included therein.

What is claimed is:

1. A display panel comprising:
a substrate having a display area and a non-display area;
a pixel electrode in the display area;
a first light emitting element bonded to the pixel electrode;
a first dummy electrode in the non-display area and adjacent to the pixel electrode;
a second light emitting element bonded to the first dummy electrode; and
a second dummy electrode connected to the first dummy electrode and in the non-display area.

2. The display panel of claim 1, further comprising a dummy connection electrode connecting the first dummy electrode and the second dummy electrode to each other.

3. The display panel of claim 1, wherein the first dummy electrode and the second dummy electrode are copper.

4. The display panel of claim 1, wherein the first dummy electrode and the second dummy electrode are on at least one of upper, lower, left, and right sides of the display area.

5. The display panel of claim 1, wherein the first dummy electrode has the same area as the pixel electrode adjacent to the first dummy electrode, and
wherein the second dummy electrode has a greater area than the first dummy electrode.

6. The display panel of claim 1, wherein the first dummy electrode comprises a first sub-dummy electrode and a second sub-dummy electrode, and
wherein the first sub-dummy electrode and the second sub-dummy electrode are connected to each other.

7. A display panel bonding temperature measurement device comprising:
a laser pressurizing head module for pressurizing light emitting elements respectively on a pixel electrode and a first dummy electrode of a substrate and for irradiating a laser beam to bond the light emitting elements to the pixel electrode and the first dummy electrode; and
a temperature measuring member for measuring a temperature on a second dummy electrode of the substrate,
wherein the substrate has a display area and a non-display area,
wherein the first dummy electrode is in the non-display area, and the second dummy electrode is connected to the first dummy electrode.

8. The display panel bonding temperature measurement device of claim 7, wherein the first dummy electrode and the second dummy electrode are copper.

9. The display panel bonding temperature measurement device of claim 7, wherein the temperature measuring member comprises:
a temperature sensor on the second dummy electrode;
a control unit for receiving a potential difference generated from the temperature sensor and processing a signal; and
a temperature display unit connected to the control unit and configured to display a temperature state measured by the temperature sensor.

10. The display panel bonding temperature measurement device of claim 9, wherein the temperature sensor is a thermocouple.

11. The display panel bonding temperature measurement device of claim 9, wherein the laser pressurizing head module comprises:
a pressurizing member comprising a first light transmitting member and a second light transmitting member and has a sealed space between the first light transmitting member and the second light transmitting member;
a gas supply unit for supplying a gas to the sealed space to generate a pressurizing force; and
a laser generator on the pressurizing member and for irradiating the laser beam in a downward direction.

12. The display panel bonding temperature measurement device of claim 11, wherein the first light transmitting member is formed of a rigid material,
the second light transmitting member is formed of an elastic material, and
the first light transmitting member and the second light transmitting member overlap a bonding area in a thickness direction.

13. The display panel bonding temperature measurement device of claim 12, wherein the first light transmitting member and the second light transmitting member overlap the second dummy electrode in the thickness direction.

14. The display panel bonding temperature measurement device of claim 11, wherein the laser generator is configured to provide area heating with respect to a bonding area.

15. The display panel bonding temperature measurement device of claim 11, wherein the laser generator is configured to radiate the laser beam to a bonding area while the second light transmitting member pressurizes the light emitting elements.

16. The display panel bonding temperature measurement device of claim 9, wherein the laser pressurizing head module comprises:
a pressurizing member comprising a first light transmitting member formed of a rigid material; and
a laser generator on the pressurizing member and for irradiating the laser beam in a downward direction.

17. The display panel bonding temperature measurement device of claim 16, wherein the laser pressurizing head module further comprises a sub-pressurizing member for pressurizing the second dummy electrode.

18. A display panel bonding temperature measurement device comprising:
a heating pressurizing head module for pressurizing light emitting elements respectively on a pixel electrode and a first dummy electrode of a substrate and for providing heat to bond the light emitting elements to the pixel electrode and the first dummy electrode; and
a temperature measuring member for measuring a temperature on a second dummy electrode of the substrate,
wherein the substrate has a display area and a non-display area, and
wherein the first dummy electrode is in the non-display area, and the second dummy electrode is connected to the first dummy electrode.

19. The display panel bonding temperature measurement device of claim 18, wherein the heating pressurizing head module comprises:
a pressurizing member comprising a first light transmitting member formed of a rigid material and for pressuring a bonding area; and
a sub-pressurizing member for pressurizing the second dummy electrode; and
a laser generator on the pressurizing member and for irradiating a laser beam in a downward direction.

20. The display panel bonding temperature measurement device of claim 18,
wherein the temperature measuring member comprises:
a temperature sensor on the second dummy electrode;
a control unit for receiving a potential difference generated by the temperature sensor and for processing a signal; and
a temperature display unit connected to the control unit and configured to display a temperature state measured by the temperature sensor, and
wherein the temperature sensor is a thermocouple.
